(19) United States
(12) Patent Application Publication
(10) Pub. No.: US 2006/0285418 A1
(43) Pub. Date: Dec. 21, 2006

(54) Semiconductor integrated circuit device, electronic component mounting board and layout designing method for the semiconductor integrated circuit device

(76) Inventor: Naoaki Aoki, Shiga (JP)

Correspondence Address: MCDERMOTT WILL & EMERY LLP, 600 13TH STREET, N.W., WASHINGTON, DC, 20005-3096, US

(21) Appl. No.: 11/450,514

(22) Filed: Jun. 12, 2006

(30) Foreign Application Priority Data
Jun. 13, 2005 (JP) P2005-172737

(51) Int. Cl. G11C 5/14

(52) U.S. Cl. 365/226

(57) ABSTRACT

A circuit configuration is adopted which supplies an internal power supply voltage from outside and inside of a semiconductor chip 1. The internal power supply voltage from the outside is supplied through an internal power supply pad 20, whereas the internal power supply voltage from the inside is supplied through a regulator 110. The regulator 110 is arranged in an area giving a remarkable level reduction due to the voltage drop in an internal power supply wiring 21a, thereby supplementing shortage in the internal power supply voltage from the internal power supply pad 20.

### BACKGROUND OF THE INVENTION

1. Field of the Invention

This invention relates to a semiconductor integrated circuit device and an electronic component mounting board incorporating a regulator for dropping an external power supply voltage, and more particularly to a layout designing method for suppressing a power supply voltage drop within the semiconductor integrated circuit device.

2. Description of the Related Art

With a finer semiconductor process, the power supply voltage supplied to an internal transistor (internal power supply voltage) has been increasingly reduced in a MOS transistor in view of the problem of the withstand voltage in its gate oxide film thickness.

On the other hand, a power supply voltage for an external interface (external power supply voltage) has been employed without being practically reduced in order to keep compatibility with other power supply voltages. It is costly to separately supply the internal power supply voltage and the external power supply voltage. Therefore, it has been effective in cost to use a regulator for dropping the external power supply voltage (e.g. 3.3 V, 2.5 V, etc.) to the internal power supply voltage (e.g. 1.5 V, 1.2 V, etc.).

In a semiconductor integrated circuit incorporating the regulator for dropping the external power supply voltage, conventionally, any internal power supply voltage was supplied from the regulator using the external power supply voltage as a supply source. Usually, the regulator is arranged in the vicinity of a power supply pad to reduce the voltage drop in the external power supply voltage due to the wiring resistance from the power supply pad to the regulator. In addition, the voltage drop in the internal power supply voltage due to the wiring resistance from the regulator to the internal circuit was reduced by incorporation of a plurality of regulators (for example, see JP-A-2002-83872).

However, in recent years, it has become too difficult to adopt a method of incorporating the regulator(s) in a large-scale semiconductor integrated circuit device.

In recent years, with a finer process particularly in a large scale semiconductor circuit, the current density has been increased so that the regulator incorporated in the semiconductor integrated circuit cannot supply a sufficient current. Namely, the limit of the current supplying capability of the regulator is problematic so that it is now very difficult to incorporate the regulator in a semiconductor chip.

Where the regulator cannot be incorporated in the semiconductor chip, the internal power supply voltage can only be directly supplied through the power supply pad from the power source (internal power supply voltage source) outside the semiconductor chip. However, in this case, in a combination with the package of the type represented by wire bonding, power supply pads are arranged on the periphery of the semiconductor chip. So, the power supply voltage is reduced owing to the voltage drop by the wiring resistance from the power supply pad to the internal circuit. Thus, the operation of the internal circuit is greatly deteriorated, which is very problematic.

With the finer process, whereas the area of the internal circuit has been decreased, fineness of an external interface has not progressed as compared with the internal circuit in order to keep the compatibility with the outside. In some semiconductor chips, their size is determined by the number of input/output pads. Actually, there is not a method for effectively using a vacant region within the semiconductor chip other than forming a decoupling capacitor in the vacant region. Therefore, the effective use of the internal region is also one of the problems to be solved.

### SUMMARY OF THE INVENTION

This invention has been accomplished in view of the above circumstance. An object of this invention is to effectively solve the problem of reduction in the level in the internal power supply voltage owing to the voltage drop in a wiring in a large scale semiconductor integrated circuit device, while also considering the effective use of a vacant space and low power consumption of a circuit.

The semiconductor integrated circuit device comprises: a first power supply pad for externally supplying an internal power supply voltage; a second power supply pad for externally supplying an external power supply voltage; a regulator for dropping the external power supply voltage supplied through the second power supply pad, creating a voltage at the same level as that of the internal power supply voltage supplied through the first power supply pad, and outputting the voltage thus created as the internal power supply voltage; an internal circuit operated by the internal power supply voltage; and an internal power source wiring electrically connected to both the first power supply pad and an output terminal of the regulator, for supplying, to the internal circuit, both the internal power supply voltage supplied through the first power supply pad and the internal power supply voltage outputted from the regulator.

In this configuration, the internal power supply voltage is supplied from both outside and inside of a semiconductor chip. Specifically, conventionally, there was only a route of supplying the internal power supply voltage from the first power supply pad (internal power supply pad). Therefore, where the internal power supply wiring is lengthened, the level reduction due to the voltage drop was problematic. On the other hand, in this invention, the regulator is provided to simultaneously create the internal power supply voltage also within the semiconductor chip. For this reason, if the circuit scale of the semiconductor integrated circuit device is increased, a large level reduction in the internal voltage supply voltage owing to the voltage drop does not occur, thereby permitting free layout design to be realized. Further, since the main internal power supply voltage is supplied from the internal power supply pad, the regulator has only to provide a current supplying capability necessary to suppress the drop in an internal power supply voltage. Usually, the output transistor area occupying the greater part of the regulator area can be reduced so that an considerable increase of the chip area does not occur. Further, by skillfully using the vacant region around the pad, the wiring for supplying the external power supply voltage to the regulator can be laid without so serious difficulty. Further, by incorporating the regulator within the semiconductor chip, the effect of substantially reducing the resistance from the power supply pad to the internal circuit can be obtained so that the width of the internal power supply wiring from the power supply pad can be reduced. Thus, the wiring region employed for the signal wiring can be increased, thereby enhancing the wiring efficiency.

In the semiconductor integrated circuit device according to this invention, the regulator is adapted to compensate for a drop in the level of the internal power supply voltage supplied from the first power supply pad by a voltage drop in the internal power supply wiring.

For example, by arranging the regulator at a position (position giving a remarkable voltage drop) where a fine power supply wiring must be laid and anxiety of circuit problem is likely occur owing to the power supply voltage drop, such an anxiety (critical problem) can be surely resolved.

In the semiconductor integrated circuit device according to this invention, the level of the internal power supply voltage outputted from the regulator is changed according to a change in the level of the internal power supply voltage supplied from the first power supply pad.

According to the operating mode (e.g. normal mode and low power consumption mode) of a semiconductor chip, when the level in the internal power supply voltage supplied from the first power supply pad is changed, correspondingly, the level in the internal power supply voltage outputted from the regulator is also changed, thereby always keeping the internal power supply voltage externally supplied and the internal power supply voltage internally created at the same level.

In the semiconductor integrated circuit device according to this invention, a wiring for supplying the external power supply voltage from the second power supply pad to the regulator is independent of another wiring for supplying the external power supply voltage to the internal circuit.

Since the regulator drops the external power supply voltage to create the internal power supply voltage, the level in the external power supply voltage supplied to the regulator must be kept as accurately as possible. Therefore, the wiring for supplying the external power supply voltage to the regulator is provided independently of another wiring for routing the external power supply voltage within the semiconductor chip. Namely, the voltage level of the other wiring for routing the external power supply voltage within the semiconductor chip is changed under the influence of the operation of the internal circuit supplied with the power supply voltage. In order to avoid this, the voltage supplying wiring for the regulator is separated, thereby making insusceptible to the operation of the internal circuit and also making it possible to adopt an unique wiring layout.

In the semiconductor integrated circuit device according to this invention, the first power supply pad is connected to a stabilizing capacitor for stabilizing the internal power supply voltage outputted from the regulator.

In this configuration, the internal power supply voltage outputted from the regulator can be stabilized.

In the semiconductor integrated circuit device according to this invention, the regulator comprises a base voltage generating circuit for generating at least one base voltage and a reference voltage generating circuit for generating a reference voltage determining the level of an output voltage from the regulator, the reference voltage generating circuit adopts the internal power supply voltage supplied from the first power supply pad as a first reference voltage and the base voltage outputted from the base voltage generating circuit as a second reference voltage, and the reference voltage generating circuit selects either the first reference voltage or the second reference voltage to generate the reference voltage.

The regulator creates the stabilized internal power supply voltage equal to the voltage level of the reference voltage (Vref). In this case, the regulator adopts a system of selecting one of a plurality of voltage signals with different levels as the reference voltage generating circuit. The plurality of voltage signals with different levels include a plurality of voltage signals (second reference voltage) created by the base voltage generating circuit and the internal power supply voltage signal itself (first reference voltage) supplied from the first power supply pad. By selecting one of the plurality of voltage signals by the reference voltage generating circuit, can be easily created the reference voltage equal to the internal power supply voltage supplied form the first power supply pad or various reference voltages (reference voltages with the level lower than the external power supply voltage) which are determined by the voltage drop in the power supply wiring formed on the semiconductor chip or the operation mode of the semiconductor chip. On the basis of the reference voltage thus created, the internal power supply voltage with the level equal to the reference voltage can be created. The regulator is arranged at the position giving a remarkable voltage drop in the internal power supply voltage within the chip so that the problem due to the level reduction in the internal power supply voltage can be dissolved. Even where the the level of the internal power supply voltage must be finely adjusted according to the position where the regulator is arranged, by variously adjusting the reference voltage in the regulator, an optimum internal power supply voltage can be outputted as circumstances demand. The regulator which is employed in this invention has only to supplement the power supply from the internal power supply pad, and is not required to have so high a current capability so that it is simple in structure and can be easily laid on the semiconductor chip.

In the semiconductor integrated circuit device according to this invention, an analog switch is employed to select either the first reference voltage or the second reference voltage.

Namely, in order to select one of the plurality of reference voltages with different reference voltages, the analog switch is employed. The analog switch is little in the distortion (fluctuation in the voltage level) and simple in the structure, thereby permitting the reference voltage to be generated while suppressing an increase in the chip area.

Further, in the semiconductor integrated circuit device according to this invention, the base voltage generating circuit generates a plurality of base voltages with different levels.

Therefore, various reference voltages (reference voltage with the level lower than the external power supply voltage) which are determined by various standards or operation modes of the semiconductor chip can be easily generated.

In the semiconductor integrated circuit device according to this invention, a wiring for supplying the internal power supply voltage supplied from the first power supply voltage to the regulator as the first reference voltage is laid in parallel to the internal power supply wiring or an external power supply wiring for supplying the external power supply voltage to the regulator.

In accordance with this configuration, the internal power supply voltage supplied from the first power supply pad to the regulator as the first reference voltage is protected from noise by the shielding effect of the power supply wiring laid in parallel in the vicinity of the regulator, and is made insusceptible to the fluctuation due to the noise.

Further, in the semiconductor integrated circuit device according to this invention, the regulator is controlled on the basis of a control signal outputted according to an operating mode of the internal circuit from a control circuit incorporated in the internal circuit.

In accordance with this configuration, according to the operation mode of the internal circuit, the level of the internal power supply voltage outputted from the regulator can be controlled.

In the semiconductor integrated circuit device according to this invention, an operating clock frequency of the internal circuit is controlled by the control signal supplied from the control circuit.

In accordance with this configuration, the frequency of the operating clock in the internal circuit can be controlled according to the operation mode of the internal circuit.

In the electronic component mounting board according to this invention, mounted are the semiconductor circuit device according to this invention, an internal power source for supplying the internal power supply voltage to the first power supply pad and an external power source for supplying the external power supply voltage to the second power supply pad.

Conventionally, on the electronic component mounting board (referred to as a mounting board or system board) on which the semiconductor chip is mounted, only the external power supply was mounted. On the other hand, in this invention, both the external power supply and internal power supply are mounted on the same mounting board. Thus, the internal power supply voltage can be supplied from outside of the semiconductor chip.

Further, in the electronic component mounting board according to this invention, the level of the internal power supply voltage supplied to the internal circuit by the regulator in the semiconductor integrated circuit device is automatically changed according to a level change in the internal power supply voltage supplied to the internal circuit in the integrated circuit device from the internal power supply.

In this invention, the internal power supply voltages are supplied from both the outside and inside of the semiconductor chip, both voltage levels must always agree with each other. To this end, the level of the voltage created inside of the chip is changed according to the level of the voltage supplied from outside of the chip.

Further, the layout designing method for a semiconductor integrated circuit device according to this invention comprises the steps of arranging an external power supply voltage pad and an internal power supply voltage pads; laying an external power supply wiring and an internal power supply wiring which are electrically connected to the external power supply voltage pad and the internal power supply voltage pad, respectively; and arranging, at a position problematic in a voltage drop in the internal power supply wiring, a regulator for dropping an external power supply voltage supplied through the external power supply voltage pad and the external power supply voltage wiring to create an internal power supply voltage, and connecting an output terminal of the regulator to the internal power supply wiring.

By supplying the internal power supply voltage from both the outside and inside of the chip, the problem in the level reduction in the internal power supply voltage due to the voltage drop is solved.

In the layout designing method for a semiconductor integrated circuit device according to this invention, the internal power supply wiring is divided into a plurality of independent wirings for each of which the regulator is provided.

Within the single semiconductor chip, the internal power supply voltage wiring is divided into a plurality of independent wirings for each of which the regulator is provided. Since the power supply voltage wiring is divided, the power supply voltages with different voltage levels can be employed for each wiring. Further, since the wiring length of each wiring is shortened to reduce the degree of the voltage drop and in addition, the voltage drop is suppressed owing to the provision of the regulator, the problem of the level reduction in the power supply voltage can be easily solved. Thus, stabilized multiple power supplies can be given in a large scale system LSI or a large scale memory LSI.

As described above, in accordance with this invention, the voltage drop in the internal power supply voltage in the semiconductor chip can be suppressed, thereby realizing a semiconductor integrated circuit with high performance.

In the semiconductor integrated circuit device incorporating the regulator according to this invention, the main internal power supply voltage is supplied from the internal power supply pad. Therefore, the regulator has only to provide a current supplying capability necessary to suppress the drop in an internal power supply voltage. Usually, the output transistor area occupying the greater part of the regulator area can be reduced so that an considerable increase of the chip area does not occur.

Further, by incorporating the regulator within the semiconductor chip, the effect of substantially reducing the resistance from the internal power supply pad to the internal circuit can be obtained so that the width of the power supply wiring from the internal power supply pad can be reduced. Thus, the wiring region employed for the signal wiring can be increased, thereby enhancing the wiring efficiency.

Further, by providing the function of controlling the output voltage from the regulator, the output voltage from the regulator can be adjusted according to the change in the internal power supply voltage. By adopting the configuration of capable of dealing with dynamic voltage control also, the low power consumption of the semiconductor chip can be realized.

As described above, by incorporating the regulator within the semiconductor chip and simultaneously supplying power from both outside and inside of the semiconductor chip, the internal region can be effectively used. In addition, the drop in the power supply voltage supplied to the internal circuit can be suppressed, thereby avoiding the critical problem accompanied by the drop in the power supply voltage.

Further, by controlling the power supply and the output voltage from the regulator according to the operation mode, low power consumption of the semiconductor chip can be realized. Further, the regulator employed in this invention has only to supplement the power supply from the internal power supply pad and is not required to have so high a current supplying capability so that it is simple in structure and can be easily laid on the semiconductor chip. Further, as a system for generating the reference voltage, a system of selecting one of various voltages by the analog switch is adopted so that the circuit configuration can be simplified.

Further, the voltage level of the wiring for routing the external power supply voltage within the semiconductor chip is changed under the influence of the operation of the internal circuit supplied with the power supply voltage. In order to avoid this, it is effective to separate the voltage supplying wiring for the regulator from the pertinent wiring, thereby suppressing the change in the internal power supply voltage supplied to the regulator and also making it possible to adopt an unique wiring layout.

Further, within the single semiconductor chip, the internal power supply voltage wiring is divided into a plurality of independent wirings for each of which at least one regulator is provided. Thus, the power supply voltages with different voltage levels can be employed for each wiring (realization of using multiple power supplies in the semiconductor chip). Further, in the case of this configuration, in addition to the merit of the multiple power supply, the following advantage can be obtained. Namely, since the wiring length of each wiring is shortened to reduce the degree of the voltage drop, and in addition, the voltage drop is suppressed owing to the provision of the regulator, the problem of the level reduction in the power supply voltage can be easily solved. Thus, stabilized multiple power supplies can be given in a large scale system LSI or a large scale memory LSI.

This invention can effectively solve the problem of reduction in the level in the internal power supply voltage owing to the voltage drop in a wiring in a large scale semiconductor integrated circuit device, while also considering the effective use of a vacant space and low power consumption of a circuit.

### BRIEF DESCRIPTION OF THE DRAWINGS

FIG. 1 is a plan view of a semiconductor chip which shows an example of the arrangement of a regulator and the layout of power supply wirings in a semiconductor integrated circuit device according to this invention.

FIG. 2 is a plan view of a semiconductor chip which shows another example of the arrangement of a regulator and the layout of power supply wirings in a semiconductor integrated circuit device according to this invention.

FIG. 3 is a plan view of a semiconductor chip which shows still another example of the arrangement of regulators and the layout of power supply wirings in a semiconductor integrated circuit device according to this invention.

FIG. 4 is a block diagram showing the circuit configuration of the semiconductor integrated circuit device according to this invention.

FIG. 5 is a circuit diagram showing an example of the internal configuration of the regulator shown in FIG. 4.

FIG. 6 is a circuit diagram showing an example of the internal configuration of the reference voltage generating circuit shown in FIG. 5 (exemplary circuit configuration using analog switches).

### DESCRIPTION OF THE PREFERRED EMBODIMENTS

Now referring to the drawings, an explanation will be given of various embodiments of this invention.

First, an explanation will be given of three embodiments for the arrangement of an regulator and the layout of power supply wirings. Subsequently, a regulator circuit will be explained. Finally, an explanation will be given of the system configuration using the semiconductor integrated circuit incorporating the regulator according to this invention.

### Embodiment 1

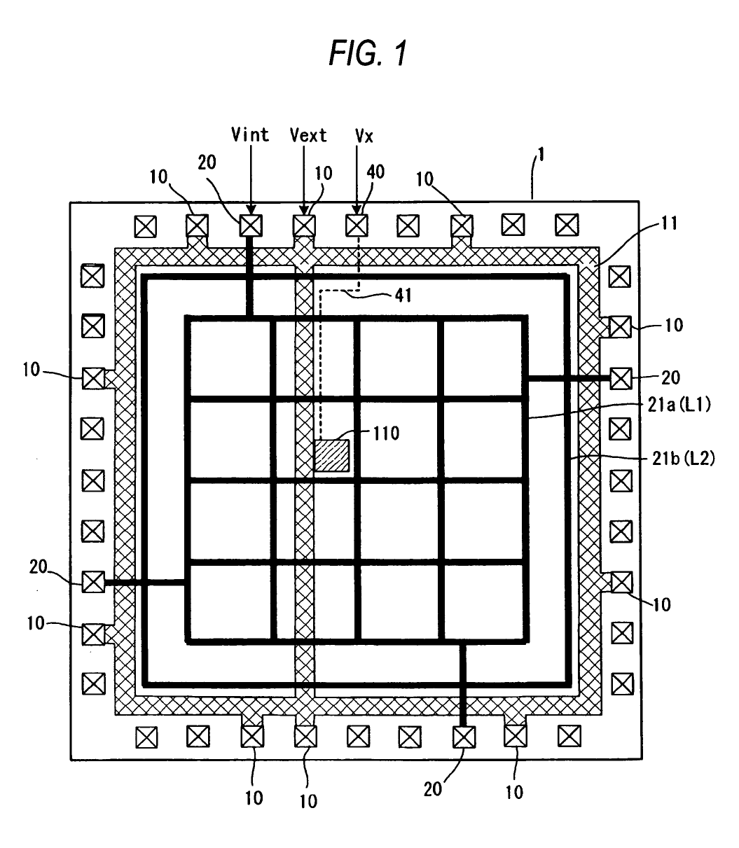

FIG. 1 is a plan view of a semiconductor chip which shows an example of the arrangement of a regulator and the layout of power supply wirings in a semiconductor integrated circuit device according to this invention.

As seen from FIG. 1, a semiconductor chip 1 has external power supply pads 10 for supplying an external power supply voltage to keep compatibility with the outside and internal power supply pads 20 for supplying an internal power supply voltage. The pads other than the external power supply pads 10 and internal power supply pads 20 are pads for an input/output signal for the semiconductor circuit device within the semiconductor chip.

The external power supply voltage supplied from outside of the semiconductor chip 1 is supplied through the external power supply pad 10 to an input/output circuit (not shown in FIG. 1) connected to the external power supply wiring 11 arranged on the periphery in the semiconductor chip 1 and a regulator 110 arranged centrally on the semiconductor chip.

Likewise, the internal power supply voltage is supplied from outside of the semiconductor chip 1 is supplied through the internal power supply pads 20 to each of circuit elements connected to internal power supply wirings 21a, 21b formed in a mesh shape and integrated on the semiconductor chip 20.

The regulator 110 is connected to the external power supply wiring 11 (wiring portion vertically cutting the center thereof) and is operated by the external power supply voltage supplied from the external power supply pad 10. The regulator creates the voltage at the potential approximately equal to the internal power supply voltage supplied from internal power supply pad 20, and supplies the voltage thus created to the internal power source wirings 21a, 21b as the internal power supply voltage.

In the large-scale integrated circuit in recent years, it is difficult to realize power supply from the point of view of the electric power and area required for the semiconductor chip using only an incorporated regulator. On the other hand, in the semiconductor chip performing power supply using only the power supply wiring without incorporating the regulator, a drop in the internal power supply voltage within the chip due to the power supply wiring resistance is remarkable. In many cases, this makes it difficult to realize the performance.

Namely, in the first embodiment of this invention, the internal power supply voltage is supplied from both the regulator 110 using the external power supply voltage as a supply source and the internal power supply pad 20. By mainly supplying the power from the internal power supply pad 20 and also supplying it from the regulator 110, the voltage drop in the internal power supply voltage is suppressed, thereby realizing the semiconductor integrated circuit device with higher performance.

Particularly, in a combination with the package of the type represented by a wire bonding, power supply pads are arranged in the peripheral region of the semiconductor chip where the input/output circuit is formed to keep compatibility with the outside. In the internal circuit using the internal power supply voltage as the supply source, at a position farther from the peripheral region of the semiconductor chip where the internal power supply pads 20 are arranged, the drop in the internal power supply voltage increases owing to the resistance of the internal power supply wirings 21a, 21b. As a result, usually, the voltage drop is most extreme at the central portion of the semiconductor chip 1.

For this reason, it is effective to locate the regulator 110 within the semiconductor chip, i.e. in the region where the input/output circuit is formed to keep the compatibility with the outside and determined by the width of the layout thereof and at a position not in contact with the region (position problematic in the voltage reduction due to the voltage drop), thereby supplying the internal power supply voltage, from the viewpoint of suppressing the drop in the internal power supply voltage, i.e. deterioration of the performance in the LSI.

The provision of the regulator within the semiconductor chip has an effect of substantially reducing the resistance of the internal power supply wiring from the internal power supply pad to the internal circuit so that the width of the internal power supply wiring from the power supply pad can be reduced. Thus, the wiring region employed for the signal wiring can be increased, thereby enhancing the wiring efficiency.

The regulator 110 is supplied with one of base potentials for determining the output from the regulator from an external base power supply pad 40 through an external base power supply wiring 41. The external base power supply wiring 41 is laid in nearly parallel to the internal power supply wirings 21a, 21b supplied with the internal power supply voltage from the internal power supply pad 20 or the external power supply wiring 11 for supplying the external power supply voltage to the regulator 110. Thus, the change in the base potential is suppressed so that the regulator 110 can produce a more stabilized voltage.

### Embodiment 2

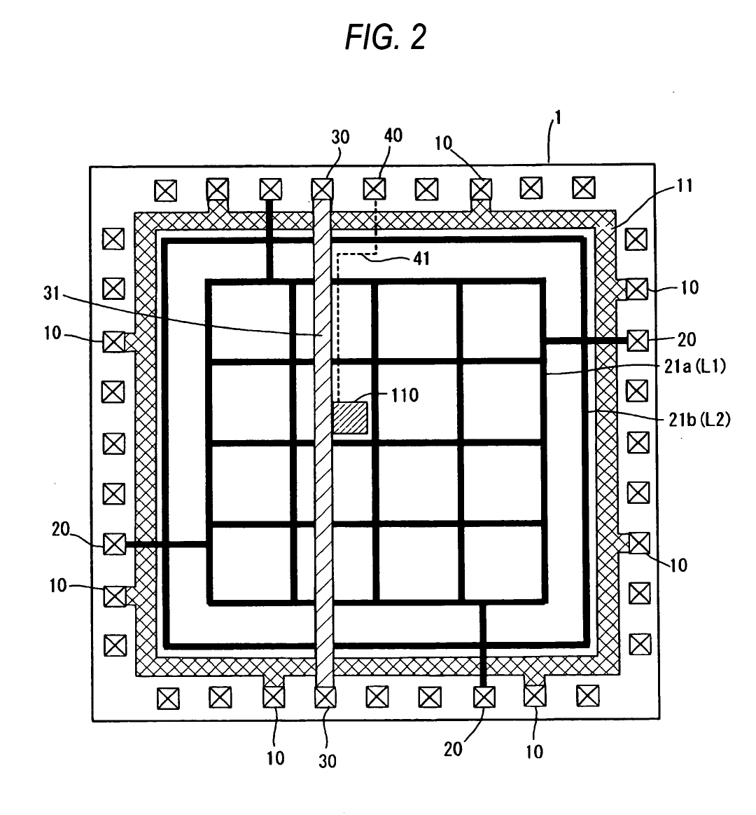

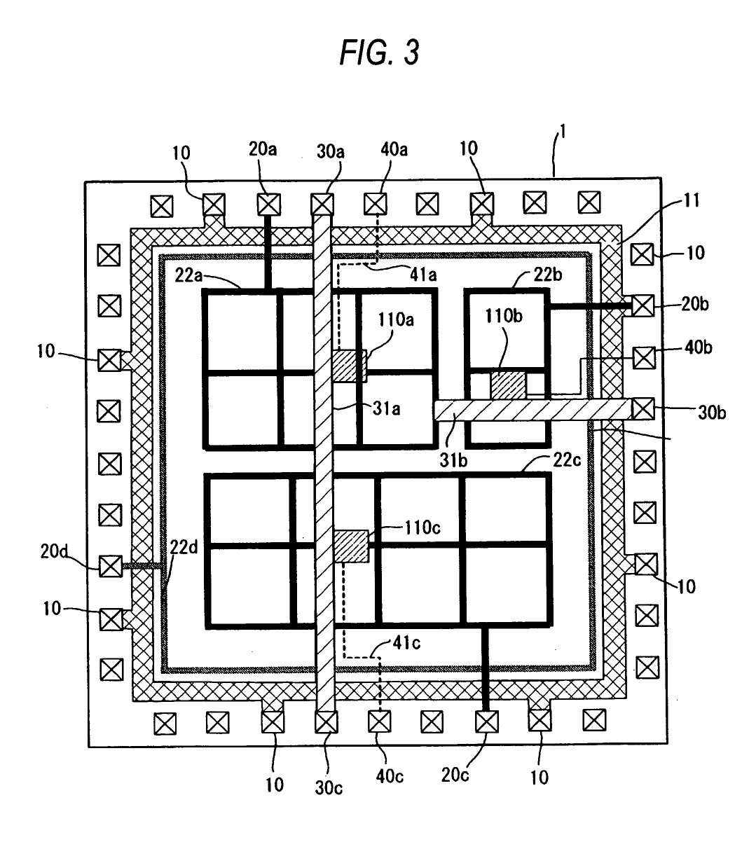

FIG. 2 is a plan view of a semiconductor chip which shows another example of the arrangement of a regulator and the layout of power supply wirings in a semiconductor integrated circuit device according to this invention. In FIG. 2, like reference numerals refer to like parts in FIG. 1 (This applies to FIG. 3 et seq.).

The feature of this embodiment resides in that an external power supply wiring 31 for supplying the external power supply voltage to the regulator 110 is provided independently of the other external power source wiring 11 for routing the external power supply voltage within the semiconductor chip, thereby stabilizing the external power supply voltage supplied to the regulator 110.

As seen from FIG. 2, the semiconductor chip 1 has external power supply pads 10 for supplying the external power supply voltage to keep compatibility with the outside, external power supply pads 30 dedicated to the regulator, and internal power supply pads 20 for supplying the internal power supply voltage. The pads other than the external power supply pads 10, 30 and internal power supply pads 20 are pads for an input/output signal for the semiconductor circuit device within the semiconductor chip.

The external power supply voltage supplied from outside of the semiconductor chip 1 is supplied through the external power supply pad 10 and the external power supply wiring 11 to the input/output circuit (not shown in FIG. 1) arranged on the periphery in the semiconductor chip 1.

Further, the external power supply voltage dedicated to the regulator, which is supplied from outside of the semiconductor chip 1, is supplied to the regulator 110 arranged centrally on the semiconductor chip 1 through the external power supply pad 30 dedicated to the regulator and the external power supply wiring 31 dedicated to the regulator.

Likewise, the internal power supply voltage supplied from outside of the semiconductor chip 1 is supplied through the internal power supply pad 20 to each of circuit elements connected to internal power supply wirings 21a, 21b formed in a mesh shape and integrated on the semiconductor chip 20.

The regulator 110 is connected to the external power supply wiring 31 dedicated to the regulator. Using the external power supply voltage supplied from the external power supply pad 30 dedicated to the regulator as the supplying source, the regulator 110 creates the voltage at the potential approximately equal to the internal power supply voltage supplied from internal power supply pad 20, and supplies the voltage thus created to the internal power source wirings 21a, 21b as the internal power supply voltage.

The regulator 110 is supplied with one of base potentials for determining the output from the regulator from the external base power supply pad 40 through the external base power supply wiring 41.

The external base power supply wiring 41 is laid in nearly parallel to the internal power supply wirings 21a, 21b or the external power supply wiring 11 for supplying the external power supply voltage to the regulator 110.

In the second embodiment of this invention, the external power supply voltage is supplied to the regulator 110 through the independent power supply pad 30 dedicated to the regulator and the external power supply wiring 31 dedicated to the regulator so that the power supply voltage with less noise can be supplied.

Since the regulator can produce the voltage with less noise, the voltage drop and fluctuation in the internal power supply voltage can be suppressed with high accuracy, thereby realizing the semiconductor integrated circuit with high performance.

### Embodiment 3

FIG. 3 is a plan view of a semiconductor chip which shows still another example of the arrangement of regulators and the layout of power supply wirings in a semiconductor integrated circuit device according to this invention.

The feature of the semiconductor integrated circuit device shown in FIG. 3 resides in that the internal power supply voltage wiring is divided into a plurality of electrically independent wirings for each of which at least one regulator is provided, thereby dealing with multiple power supplies.

As seen from FIG. 3, the semiconductor chip 1 dealing with the multiple power supplies has external power supply pads 10 for supplying the external power supply voltage to keep compatibility with the outside, external power supply pads 30a, 30b, 30c dedicated to the regulators, and internal power supply pads 20a to 20d for supplying the internal power supply voltage, which are connected to the external power supply wiring 11 and the internal power supply wirings 22a to 22d, respectively.

In order to keep the compatibility with the outside, the external power supply voltage supplied from outside of the semiconductor chip 1 is supplied through the external power supply pad 10 and the external power supply wiring 11 to the input/output circuit (not shown in FIG. 1) arranged on the periphery in the semiconductor chip 1.

Likewise, the internal power supply voltage is supplied from outside of the semiconductor chip 1 is supplied through the internal power supply pads 20a to 20d and the internal power supply wirings 22a to 22d to the circuits belonging to the respective internal power supply voltage regions integrated on the semiconductor chip 1.

Regulators 110a to 110c are supplied with the external power supply voltage from the external power supply pads 30a to 30c dedicated to the regulators through external power supply wirings 31a, 31b. The regulators 110a to 110c drop the external power supply voltage to create the voltage with a voltage level equal to the internal power supply voltage supplied from the outside and supplies the voltage thus created to the internal power source wirings 22a to 22c as the internal power supply voltage.

Where the semiconductor chip 1 dealing with the multiple power supplies is supplied with electric power through only the power supply wirings without incorporating any regulator, in the normal operation, the drop in the internal power supply voltage is more remarkable at a position farther from the internal power supply pad (power supply point) owing to the resistance of the internal power supply wiring.

Thus, the voltage level is usually lower than the voltage directly supplied to the internal power source pads 20a, 20b, 20c.

In short, in the third embodiment of this invention, by arranging the regulator in an area giving a remarkable voltage drop in the internal power supply voltage in each of power supply regions of the semiconductor chip 1 dealing with the multiple power supplies, the voltage drop can be suppressed, thereby realizing the semiconductor integrated circuit with higher performance.

Further, the layout configuration of this invention has the effect of permitting the multiple power supplies to be dealt with and also has an effect that even where a single power supply voltage is used, by limiting the length of the power supply wiring, an increase in the degree of the voltage drop can be restrained.

### Embodiment 4

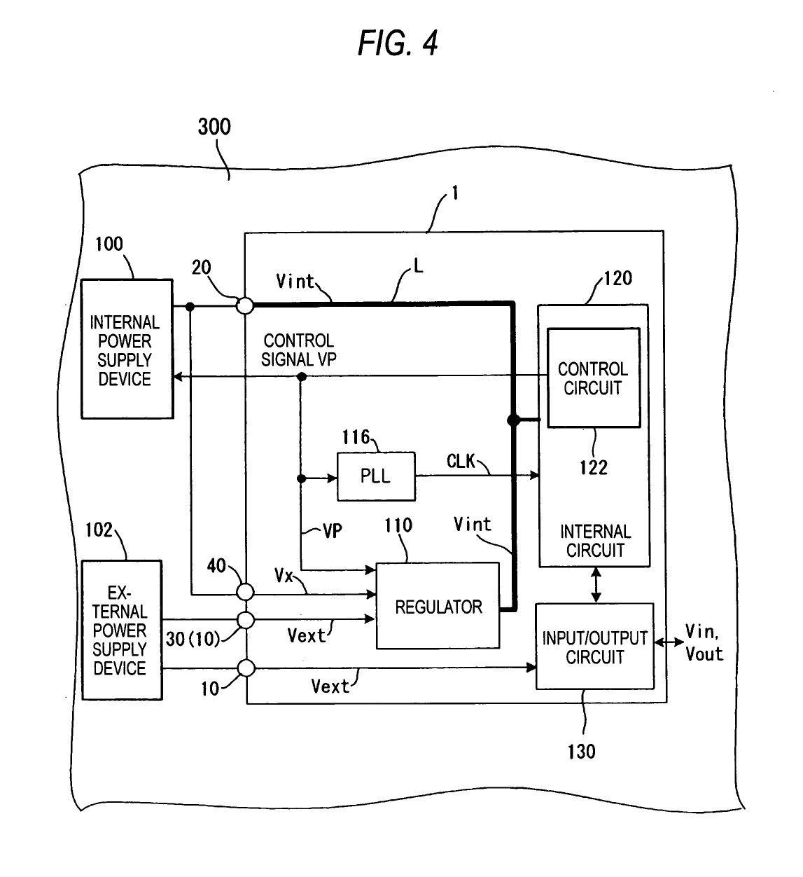

In this embodiment, an explanation will be given of an example of the concrete circuit configuration of a semiconductor integrated circuit device according to this invention. FIG. 4 is a block diagram showing the circuit configuration of the semiconductor integrated circuit device according to this invention. In FIG. 4, like reference numerals refer to like parts in the previous drawings.

As seen from FIG. 4, the semiconductor chip 1 is mounted on an electronic component mounting board (also referred to as a system board). In the vicinity of the semiconductor chip 1, an internal power supply device 100 and an external power supply device 102 are provided.

The semiconductor chip 1 includes a regulator 110, a PLL circuit 116, an internal circuit 120 (incorporating a control circuit 122), an input/output circuit 130 and power supply pads 10 to 40 shown in FIGS. 1 to 3.

The control circuit 122 produces an internal power supply voltage and a clock signal for controlling a clock frequency.

The feature of the circuit configuration of FIG. 4 resides in that an internal power supply wiring L (corresponding to reference numerals 21a, 21b in FIG. 1) is electrically connected to both the internal power supply device 100 and regulator 110, and hence the internal power supply voltage is supplied from both outside and inside of the semiconductor chip 1 and supplied to the internal circuit 120.

The control circuit 122 supplies a control signal VP to the internal power supply device 100 to regulate the level of the internal power supply voltage.

This control signal VP controls the PLL circuit 116 so that the frequency of the clock supplied to the internal circuit 120 is regulated.

Further, the control signal VP regulates the voltage level of the internal power supply voltage generated from the regulator 110.

Actually, in order to execute certain processing, a necessary processing performance is previously determined. Correspondingly, it is only necessary that a clock frequency and the power supply voltage operating at this clock frequency are given. In this way, by using the same control signal VP for control of both frequency and regulator, the frequency and voltage can be easily controlled, thereby reducing the wiring area of the control signal within the semiconductor chip 1.

In accordance with this configuration, the internal power supply voltage and the clock frequency can simultaneously controlled. This provides the system with higher power efficiency, high performance and low power consumption.

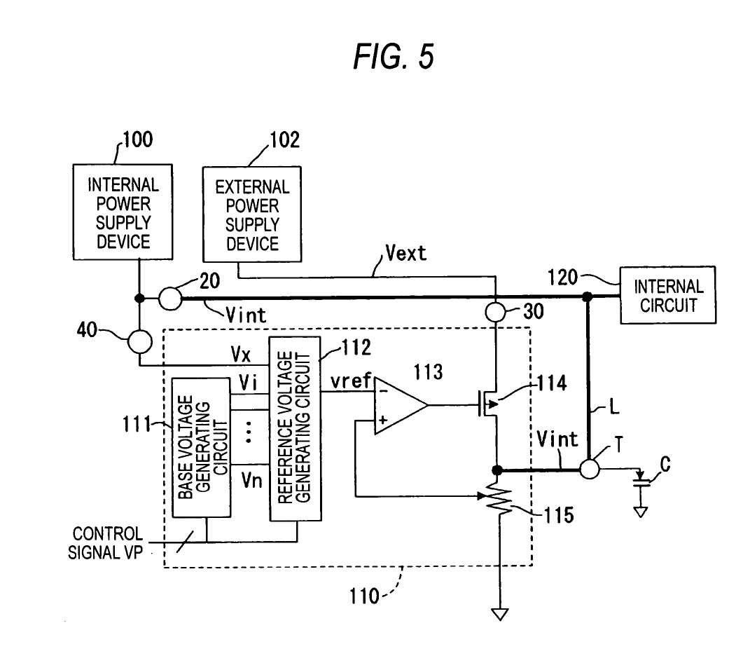

FIG. 5 is a circuit diagram showing an example of the internal configuration-of the regulator shown in FIG. 4.

As seen from FIG. 5, the regulator 110 includes a base voltage generating circuit 111, a reference voltage generating circuit 112 and an operational amplifier (differential amplifier circuit) 113, a PMOS transistor 113 and a potentiometer 115.

To the inverting terminal of the operational amplifier 113, a reference voltage Vref is supplied whereas to the non-inverting terminal thereof, a divided voltage of the potentiometer (variable resistor) 115 (serving as an internal power supply voltage Vint which is an output from the regulator) is supplied. Since the inverting terminal and non-inverting terminal of the operational amplifier 113 are virtually grounded, Vint is stabilized so that Vint=Vref. Between the output terminal of the operational amplifier 113 and the potentiometer 115, a PMOS transistor 114 is located. Since the voltage lever is inverted between the gate and drain of the PMOS transistor 114, the output voltage serving as Vint (internal power supply voltage) is resultantly stabilized through the negative feedback control using the gain of the operational amplifier 113.

The base voltage generating circuit 111 can generate a plurality of base voltages V1 to Vn with different voltage levels (the voltage level is lower than the external power supply voltage Vext). Which base voltage is generated is controlled by the control signal VP from the control circuit 122 (FIG. 4). The base voltages V1 to Vn are supplied to the reference voltage generating circuit 112 as a first reference voltage.

Further, in addition to the base voltage (V1 to Vn) serving as the first reference voltage, the internal power supply voltage from the internal power supply device 100 is given to the reference voltage generating circuit 112 as a second reference voltage Vx. In accordance with the control signal VP, the reference voltage generating circuit 112 selects one of the signals Vi to Vn and Vx and produces the selected signal as the reference voltage Vref. Using the negative feedback control using the operational amplifier as described above, the voltage equal to the voltage value of the reference voltage Vref is created. The voltage created is supplied to the internal power supply wiring L (corresponding to reference numerals 21a (L1), 21b (L2) as the internal power supply voltage Vint.

The voltage level of the internal power supply voltage (Vint) outputted from the regulator 110 must be finely adjusted according to the degree of the voltage drop in the power supply wiring. This fine adjustment is carried out using the control signal VP.

Since the internal power supply voltage from the internal power supply device 100 is given to the reference voltage generating circuit 112 as the second reference voltage Vx, if the voltage Vx is selected as the reference voltage Vref, the internal power supply voltage having the voltage value equal to Vx can be easily outputted from the regulator 110. Thus, also when the output voltage from the internal power supply device 100 is changed according to the operation mode of the internal circuit 120, correspondingly, the output voltage from the regulator 110 can be automatically changed (adjusted). Accordingly, the power supply voltage in the semiconductor chip 1 can be adjusted optionally, thereby realizing the semiconductor chip with high performance and low power consumption.

In the circuit of FIG. 5, if the potential of the internal power supply voltage (reference voltage Vx) supplied from the internal power supply device 100 located outside the semiconductor chip 1 is directly changed and the level change in the internal power supply voltage (Vint) generated from the regulator 110 is observed, the operation performance of the regulator 110 can be easily tested.

As shown at lower right position in FIG. 5, a stabilizing capacitor C is connected to the output terminal of the regulator 110 through terminal T, the level change in the internal power supply voltage (Vint) generated from the regulator 110 is difficult to occur, thereby permitting the voltage level to be stabilized.

Further, as seen from FIGS. 1 to 3, if the base power supply wiring (reference numeral 41 in FIG. 1) for supplying the second reference voltage Vx to the regulator 110 is laid in nearly parallel to the internal power supply wiring supplied with the internal power supply voltage from the internal power supply pad or the external power supply wiring for supplying the external power supply voltage to the regulator, the change in Vx due to noise can be suppressed, thereby permitting Vx to be precisely supplied to the regulator 110.

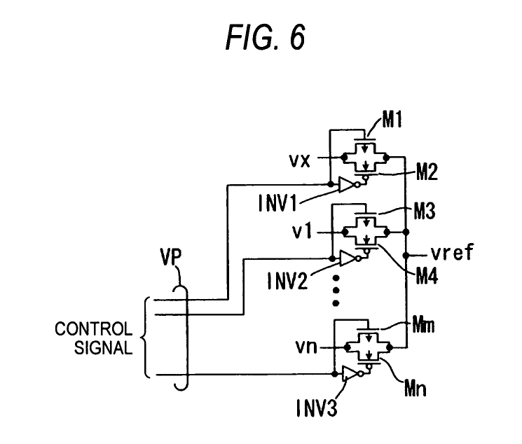

FIG. 6 is a circuit diagram showing an example of the internal configuration of the reference voltage generating circuit (reference numeral 115) shown in FIG. 5.

As seen from FIG. 6, the reference voltage generating circuit 112 includes a plurality of analog switches including complementary MOS transistors (M1 and M2, M3 and M4, Mm and Mn) and inverters INV1 to INV3.

Any one analog switch is turned on by the control signal VP. Thus, any one of Vx and V1 to Vn is produced as the reference voltage Vref. By using the analog switch, the precise voltage with less distortion can be supplied to the operational amplifier 113 at the subsequent stage. Further, this circuit is simple in configuration and so gives the effect that an increase in the chip area can be suppressed.

As understood from the description hitherto made, in accordance with this invention, the voltage drop in the internal power supply voltage in the semiconductor chip can be suppressed, thereby realizing a semiconductor integrated circuit with high performance.

In the semiconductor integrated circuit device incorporating the regulator according to this invention, the main internal power supply voltage is supplied from the internal power supply pad. Therefore, the regulator has only to provide a current supplying capability necessary to suppress the drop in an internal power supply voltage. Usually, the output transistor area occupying the greater part of the regulator area can be reduced so that an considerable increase of the chip area does not occur.

Further, by incorporating the regulator within the semiconductor chip, the effect of substantially reducing the resistance from the internal power supply pad to the internal circuit can be obtained so that the width of the power supply wiring from the power supply pad can be reduced. Thus, the wiring region employed for the signal wiring can be increased, thereby enhancing the wiring efficiency.

Further, by providing the function of controlling the output voltage from the regulator, the output voltage from the regulator can be adjusted according to the change in the internal power supply voltage. By adopting the configuration of capable of dealing with dynamic voltage control also, the low power consumption of the semiconductor chip can be realized.

As described above, by incorporating the regulator within the semiconductor chip and simultaneously supplying power from both outside and inside of the semiconductor chip, the internal region can be effectively used. In addition, the drop in the internal power supply voltage supplied to the internal circuit can be suppressed, thereby avoiding the critical problem accompanied by the drop in the power supply voltage.

Further, by controlling the power supply and the output voltage from the regulator according to the operation mode, low power consumption of the semiconductor chip can be realized. Further, the regulator employed in this invention has only to supplement the power supply from the internal power supply pad and is not required to have so high a current supplying capability so that it is simple in structure and can be easily laid on the semiconductor chip. Further, as a system for generating the reference voltage, a system of selecting one of various voltages by the analog switch is adopted so that the circuit configuration can be simplified.

Further, the voltage level of the wiring for routing the external power supply voltage within the semiconductor chip is changed under the influence of the operation of the internal circuit supplied with the internal power supply voltage. In order to avoid this, it is effective to separate the voltage supplying wiring for the regulator from the pertinent wiring, thereby suppressing the change in the internal power supply voltage supplied to the regulator and also making it possible to adopt an unique wiring layout.

The regulator is arranged at the position giving a remarkable voltage drop in the internal power supply voltage within the chip. So, the distance from peripheral pads is increased and the power supply wiring to the regulator is also lengthened. This influences the output voltage from the regulator due to the wiring resistance. However, by variously adjusting the reference voltage in the regulator which determines the output voltage therefrom, an optimum output voltage can be outputted as circumstances demand.

Further, within the single semiconductor chip, the internal power supply voltage wiring is divided into a plurality of independent wirings for each of which at least one regulator is provided so that the wiring length of each wiring is shortened to reduce the degree of the voltage drop. In addition, the effect of suppressing the voltage drop owing to the provision of the regulator can be given. Thus, the problem of the level reduction in the power supply voltage can be easily solved. Accordingly, stabilized power supply can be executed in a large scale system LSI or a large scale memory LSI.

This invention can effectively solve the problem of reduction in the level in the internal power supply voltage owing to the voltage drop in a wiring in a large scale semiconductor integrated circuit device, while also considering the effective use of a vacant space and low power consumption of a circuit.

This invention gives the effect of realizing a large scale semiconductor circuit device capable of effectively suppressing the drop in the power supply voltage, and hence is effectively applied to a memory LSI such as DRAM and a semiconductor integrated circuit device such as a system LSI, an electronic component mounting board with the semiconductor integrated circuit device mounted thereon, and a layout method for the semiconductor integrated circuit device.

What is claimed is:

1. A semiconductor integrated circuit device, comprising:
a first power supply pad, externally supplying an internal power supply voltage;
a second power supply pad, externally supplying an external power supply voltage;
a regulator, dropping the external power supply voltage supplied through the second power supply pad, creating a voltage at the same level as that of the internal power supply voltage supplied through the first power supply pad, and outputting the voltage thus created as the internal power supply voltage;
an internal circuit, operated by the internal power supply voltage; and
an internal power source wiring, electrically connected to both the first power supply pad and an output terminal of the regulator, for supplying, to the internal circuit, both the internal power supply voltage supplied through the first power supply pad and the internal power supply voltage outputted from the regulator.

2. The semiconductor integrated circuit device according to claim 1, wherein the regulator is adapted to compensate for a drop in the level of the internal power supply voltage supplied from the first power supply pad by a voltage drop in the internal wiring.

3. The semiconductor integrated circuit device according to claim 1, wherein the level of the internal power supply voltage outputted from the regulator is changed according to a change in the level of the internal power supply voltage supplied from the first power supply pad.

4. The semiconductor integrated circuit device according to claim 1, wherein a wiring for supplying the external power supply voltage from the second power supply pad to the regulator is independent of another wiring for supplying the external power supply voltage to the internal circuit.

5. The semiconductor integrated circuit device according to claim 1, wherein the first power supply pad is connected to a stabilizing capacitor for stabilizing the internal power supply voltage outputted from the regulator.

6. The semiconductor integrated circuit-device according to claim 3, wherein:
the regulator comprises a base voltage generating circuit, generating at least one base voltage and a reference voltage generating circuit, generating a reference voltage determining the level of an output voltage from the regulator;
the reference voltage generating circuit adopts the internal power supply voltage supplied from the first power supply pad as a first reference voltage and the base voltage outputted from the base voltage generating circuit as a second reference voltage; and
the reference voltage generating circuit selects either the first reference voltage or the second reference voltage to generate the reference voltage.

7. The semiconductor integrated circuit device according to claim 6, wherein the reference voltage generating circuit comprises an analog switch for selecting either the first reference voltage or the second reference voltage.

8. The semiconductor integrated circuit device according to claim 6, wherein the base voltage generating circuit generates a plurality of base voltages with different levels.

9. The semiconductor integrated circuit device according to claim 6, wherein a wiring for supplying the internal power supply voltage supplied from the first power supply voltage to the regulator as the first reference voltage is laid in parallel to the internal power supply wiring or an external power supply wiring for supplying the external power supply voltage to the regulator.

10. The semiconductor integrated circuit device according to claim 3, wherein the regulator is controlled on the basis of a control signal outputted according to an operating mode of the internal circuit from a control circuit incorporated in the internal circuit.

11. The semiconductor integrated circuit device according to claim 10, wherein an operating clock frequency of the internal circuit is controlled by the control signal supplied from the control circuit.

12. The electronic component mounting board on which the semiconductor circuit device according to claim 1, and an internal power source for supplying the internal power supply voltage to the first power supply pad and an external power source for supplying the external power supply voltage to the second power supply pad are mounted.

13. The electronic component mounting board according to claim 12, wherein the level of the internal power supply voltage supplied to the internal circuit by the regulator in the semiconductor integrated circuit device is automatically changed according to a level change in the internal power supply voltage supplied to the internal circuit in the integrated circuit device from the internal power source.

14. A layout designing method for a semiconductor integrated circuit device, comprising the steps of:
arranging an external power supply voltage pad and an internal power supply voltage pad;
laying an external power supply wiring and an internal power supply voltage wiring which are electrically connected to the external power supply voltage pad and the internal power supply voltage pad, respectively; and
arranging, at a position problematic in a voltage, drop in the internal power supply wiring, a regulator for dropping an external power supply voltage supplied through the external power supply voltage pad and the external power supply voltage wiring to create an internal power supply voltage, and connecting an output terminal of the regulator to the internal power supply wiring.

15. A layout designing method for a semiconductor integrated circuit device according to claim 14, wherein the internal power supply wiring is divided into a plurality of independent wirings for each of which the regulator is provided.
